(19) United States
(12) Patent Application Publication
(10) Pub. No.: US 2014/0264869 A1
(43) Pub. Date: Sep. 18, 2014

(54) Semiconductor Device

(71) Applicants: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(72) Inventors: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(21) Appl. No.: 13/834,806

(22) Filed: Mar. 15, 2013

(51) Int. Cl. H01L 23/532; H01L 23/522

(52) U.S. Cl. CPC H01L 23/53238; H01L 23/5226
USPC 257/751; 257/774

(57) ABSTRACT

A semiconductor device comprises a substrate having a first side with a first surface and a second side with a second surface, a recessed through silicon via (TSV) penetrating the substrate and forming a first step height with respect to the first surface of the first side, a first extruded backside redistribution line (RDL) filling in the first step height and engaging with the recessed through silicon via.

### FIELD OF THE INVENTION

The present invention relates to a semiconductor device and particularly to a semiconductor device with a through-silicon via.

### BACKGROUND OF THE INVENTION

To save precious layout space or increase interconnection efficiency, multiple chips of integrated circuits (ICs) can be stacked together as a single IC package. To that end, a three-dimensional (3D) stack packaging technology is used to package the chips of integrated circuits. Through-silicon vias (TSVs) are widely used to accomplish the 3D stack packaging technology. A through-silicon via is a vertical conductive via completely passing through a silicon wafer, a silicon board, a substrate of any material or die. Nowadays, a 3D integrated circuit (3D IC) is applied to a lot of fields such as memory stacks, image sensors or the like.

Although through-silicon vias comes with a lot of advantages, they also introduce new issues into 3D IC architecture. Electrical currents coming through TSVs would be much stronger in strength compared to electrical current flowing through a single transistor or an interconnect metal line, so weak points within TSVs would become reliability breach points. There is a need to improve the weak points within TSVs, thereby improving their reliability.

### SUMMARY OF THE INVENTION

In one embodiment of the present invention, a semiconductor device is provided to comprise a substrate having a first side with a first surface and a second side with a second surface, a recessed through silicon via (TSV) penetrating the substrate and forming a first step height with respect to the first surface of the first side and a first extruded backside redistribution line (RDL) filling in the first step height and engaging with the recessed through silicon via.

In another embodiment of the present invention, a semiconductor device is provided to comprise a substrate with a first side and a second side, a through silicon via (TSV) penetrating the substrate, a first backside redistribution line (RDL) disposed on the first side in direct contact with the through silicon via and a current distributing layer within the through silicon via and substantially parallel to the substrate to transect the through silicon via into at least two portions.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 shows a schematic cross-sectional view of a semiconductor device with a through-silicon via (TSV) and backside redistribution lines (RDLs) in accordance with a known art;

FIG. 2 shows a schematic cross-sectional view of a semiconductor device with a through-silicon via (TSV) and a backside redistribution line (RDL) in accordance with an embodiment of the present invention;

FIG. 3 shows a schematic cross-sectional view of a semiconductor device with a through-silicon via (TSV) and backside redistribution line (RDLs) in accordance with another embodiment of the present invention;

FIG. 4 shows a schematic cross-sectional view of a semiconductor device with a through-silicon via (TSV) and backside redistribution line (RDLs) in accordance with still another embodiment of the present invention;

FIG. 5 shows a schematic cross-sectional view of a semiconductor device with a through-silicon via (TSV) and backside redistribution line (RDLs) in accordance with still another embodiment of the present invention.

### DETAILED DESCRIPTION OF PREFERRED EMBODIMENTS

The following is the detailed description of the preferred embodiments of this invention. All the elements, sub-elements, structures, materials, arrangements recited herein can be combined in any way and in any order into new embodiments, and these new embodiments should fall in the scope of this invention defined by the appended claims. A person skilled in the art, upon reading this invention, should be able to modify and change the elements, sub-elements, structures, materials, arrangements recited herein without being apart from the principle and spirit of this invention. Therefore, these modifications and changes should fall in the scope of this invention defined only by the following claims.

There are a lot of embodiments and figures in this application. To avoid confusions, similar components are represented by same or similar numerals. To avoid complexity and confusions, only one of the repetitive components is marked. Figures are meant to deliver the principle and spirits of this invention, so the distance, size, ratio, shape, connection relationship, etc. are examples instead of realities. Other distance, size, ratio, shape, connection relationship, etc. capable of achieving the same functions or results can be adopted as equivalents.

Now refer to FIG. 1, which shows a schematic cross-sectional view of a semiconductor device with a through-silicon via (TSV) and backside redistribution lines (RDLs) in accordance with a known art. Through-silicon via (TSV) (in some references also known as through electrode, conductive post . . . etc.) 1000 passes “through” the substrate 100 and physically and electrically connect the backside and front side of substrate 100. TSV 1000 comprises a dielectric layer 150 lining the sidewall of the through-silicon hole accommodating the TSV 1000 and a conductive filler comprising a barrier/glue layer 900 lining on the dielectric layer 150 and a low-resistivity layer 800. The dielectric layer 150 may be a silicon dioxide layer or a silicon nitride layer. The barrier/glue layer 900 may comprise Ta, TaN, Ti, TiN, W, WN, Mo, Mn and/or Cu and the low-resistivity layer 800 may comprise W, Cu and/or Al.

On both backside and front side of the substrate 100, there are backside redistribution lines (RDLs) for routing and a dielectric layer to isolate different RDLs. In FIG. 1, a dielectric layer 150″ is disposed on the front side and a RDL comprising a barrier/glue layer 510 and a low-resistivity layer 500 is disposed on the dielectric layer 150″. Similarly on the backside, a dielectric layer 150′ is disposed on the back side and a RDL comprising a barrier/glue layer 510′ and a low-resistivity layer 500′ is disposed on the dielectric layer 150′. The functions of RDLs can be understood as connections between different TSV and/or connections between TSV and micro bumps/bumps (not shown), so RDLs are similar to interconnects for active device routing and may come with several layers disposed along a vertical direction within one or more dielectric/isolation layers.

Compared to normal active devices such as transistors, a TSV has a much bigger size in a scale of micrometers. In one embodiment, a TSV has a diameter of about 30 μm. In another embodiment, a TSV has a diameter of about 10 μm. In a further embodiment, a TSV has a diameter of about 6 μm. Therefore, electrical currents flowing through TSVs will be much stronger in strength compared to electrical currents flowing through transistors. Furthermore, the resistivity of the barrier/glue layer 510/510′ is usually ten times or even hundred times more than the resistivity of the low-resistivity layer 500/500′, so barrier/glue layer is a better heat generating layer than the low-resistivity layer. In FIG. 1, since the boundary of barrier/glue layer 510 of the RDL and barrier/glue layer 900 of TSV 1000 is right at the trench corner, that boundary becomes a electron migration weak point due to current concentrating and self-heating feature of the barrier/glue layers. Therefore, a novel structure is needed to improve this issue.

Now please refer to FIG. 2, which shows a schematic cross-sectional view of a semiconductor device with a through-silicon via (TSV) and a backside redistribution line (RDL) in accordance with an embodiment of the present invention. In FIG. 2, there is nothing on the front side except TSV 1000. However, active devices and interconnect structures may be deployed on the front side and they are omitted from the figure to keep the figure plain and simple. Not like the known art shown in FIG. 1, the embodiment shown in FIG. 2 has a recessed TSV 1000 and a extruded RDL that makes the boundary of barrier/glue layer 510′ of the RDL and barrier/glue layer 900 of TSV 1000 away from the trench corner. There is a step height between the recessed TSV 1000 and backside surface of the substrate 100 as shown in FIG. 2. It is noted that the recessed TSV 1000 and the extruded RDL are perfectly engage together so the extruded RDL fill in the step height and can be more secured in position. The substrate is similar to the one described with respect to FIG. 1. The materials used for TSV 1000, RDL and dielectric layer 150′ are essentially the same as the ones used in FIG. 1.

Now please refer to FIG. 3, which shows a schematic cross-sectional view of a semiconductor device with a through-silicon via (TSV) and backside redistribution line (RDLs) in accordance with another embodiment of the present invention. The embodiment of FIG. 3 is similar to the embodiment of FIG. 2, the only difference is on the front side. TSV 1000 has a recess on the front side 1000 to engage the extruded RDL on the front side that the boundary of barrier/glue layer 510 of the front side RDL and barrier/glue layer 900 of TSV 1000 is allowed to be away from the trench corner. It is worth mentioning that one of the front side and back side RDLs may be replaced by an interconnect structure such as metal one. With both the front side and back side RDLs, the substrate 100 can be used as an interposer configured to couple different chips.

Now please refer to FIGS. 4 and 5, which show a schematic cross-sectional view of a semiconductor device with a through-silicon via (TSV) and backside redistribution line (RDLs) in accordance with still another embodiment of the present invention. Although in FIGS. 4 and 5, the boundary of different barrier/glue layers is still at the trench corner, at least one inner barrier/glue layer 910 is added within the TSV 1000 to act as a current distributing layer to redistribute electrical current. To this end, the material/materials used for the inner barrier/glue layer 910 could be the same with the material/materials used for barrier/glue layer 900 but should be different from the material/materials used for the low-resistivity layer 800. For example, when the low-resistivity layer uses Cu as its material, the inner barrier/glue layer 910 and the barrier/glue layer 900 may comprise Ti, TiN, Ta, TaN and/or Mn. The distance between the inner barrier/glue layer 910 and the substrate surface can be adjusted according to performance required or complexity of manufacturing process; the inner barrier/glue layer 910 can be disposed further away from the substrate surface as shown in FIG. 4 or it can be disposed further close to the substrate surface as shown in FIG. 5. The at least one inner barrier/glue layer 910 is substantially parallel to the substrate surface and transects the through silicon via 1000 into at least two portions along the thickness direction of the substrate 100.

By shifting the boundary of barrier/glue layer of TSV 1000 and RDL away from trench corner or by adding inside barrier/glue layers within TSV 1000, the present invention can solve the reliability issue caused by current concentrating and self-heating of barrier layer.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device, comprising:
a substrate having a first side with a first surface and a second side with a second surface;
a recessed through silicon via (TSV) penetrating the substrate and forming a first step height with respect to the first surface of the first side; and
a first extruded backside redistribution line (RDL) filling in the first step height and engaging with the recessed through silicon via.

2. The semiconductor device of claim 1, wherein the first side is the backside of the substrate.

3. The semiconductor device of claim 1, wherein recessed through silicon via comprises a through silicon hole within the substrate, a dielectric layer lining on the sidewall of the through silicon hole, a barrier/glue layer lining on the dielectric layer and a low-resistivity layer filling the through silicon hole.

4. The semiconductor device of claim 1, wherein the first extruded backside redistribution line comprises a barrier/glue layer and a low-resistivity layer on the barrier/glue layer.

5. The semiconductor device of claim 1, wherein the recessed through silicon via forms a second step height with respect to the second surface of the second side.

6. The semiconductor device of claim 5, further comprising a second extruded backside redistribution line filling in the second step height and engaging with the recessed through silicon via.

7. A semiconductor device, comprising:
a substrate with a first side and a second side;
a through silicon via (TSV) penetrating the substrate;
a first backside redistribution line (RDL) disposed on the first side in direct contact with the through silicon via; and
a current distributing layer, within the through silicon via and substantially parallel to the substrate, transecting the through silicon via into at least two portions.

8. The semiconductor device of claim 7, wherein the first side is the backside of the substrate.

9. The semiconductor device of claim 7, further comprising a second backside redistribution line disposed on the second side in direct contact with the through silicon via.

10. The semiconductor device of claim 7, wherein the through silicon via comprises a through silicon hole within the substrate, a dielectric layer lining on the sidewall of the through silicon hole, a barrier/glue layer lining on the dielectric layer and a low-resistivity layer filling the through silicon hole.

11. The semiconductor device of claim 10, wherein the barrier/glue layer and the current distributing layer use the same material/materials.

12. The semiconductor device of claim 11, wherein the barrier/glue layer and the current distributing layer use Ti, TiN, Ta, TaN and/or Mn.

13. The semiconductor device of claim 10, wherein the low-resistivity layer and the current distributing layer use different material/materials.

14. The semiconductor device of claim 10, wherein the current distributing layer use Cu.
